(19) United States
(12) Patent Application Publication
(10) Pub. No.: US 2022/0356581 A1
(43) Pub. Date: Nov. 10, 2022

(54) GAS SUPPLY DEVICE AND GAS SUPPLY METHOD

(71) Applicant: Tokyo Electron Limited, Minato-ku, Tokyo (JP)

(72) Inventors: Kensaku NARUSHIMA, Nirasaki City, Yamanashi (JP); Takanobu HOTTA, Nirasaki City, Yamanashi (JP); Atsushi MATSUMOTO, Nirasaki City, Yamanashi (JP); Takuya KAWAGUCHI, Nirasaki City, Yamanashi (JP); Tomohisa KIMOTO, Nirasaki City, Yamanashi (JP)

(21) Appl. No.: 17/753,886

(22) PCT Filed: Sep. 16, 2020
(86) PCT No.: PCT/JP2020/035136

§ 371 Date: Mar. 17, 2022

(30) Foreign Application Priority Data
Sep. 24, 2019 (JP) 2019-173173

(51) Int. Cl. C23C 16/52; C23C 16/455

(52) U.S. Cl. CPC C23C 16/52; C23C 16/45557; C23C 16/45544; C23C 16/45561

(57) ABSTRACT

A gas supply device that supplies a processing gas to a processing container storing a substrate and performs a process includes: a raw material container configured to accommodate a liquid raw material or a solid raw material; a carrier gas supply configured to supply a carrier gas into the raw material container; a gas supply path configured to supply the processing gas, which includes the raw material that has been vaporized and the carrier gas, from the raw material container to the processing container; a flow meter provided in the gas supply path and configured to measure a flow rate of the processing gas; and a constricted flow path provided on a downstream side of the flow meter in the gas supply path and configured to increase an average pressure value between the constricted flow path and the flow meter in the gas supply path.

### TECHNICAL FIELD

The present disclosure relates to a gas supply device and a gas supply method.

### BACKGROUND

In a semiconductor device manufacturing process, various gas processes are performed on a semiconductor wafer (hereinafter, referred to as a “wafer”) as a substrate. As one of the gas processes, for example, there is film formation through atomic layer deposition (ALE). Patent Document 1 discloses a film forming apparatus including a gas supply mechanism for supplying tungsten hexachloride (WCl₆) gas to a processing container in order to form a tungsten (W) film on a wafer through ALD. The gas supply mechanism includes a raw material tank in which WCl₆ as a solid raw material is accommodated, a gas source configured to supply a carrier gas to the raw material tank, and a gas supply line connecting the raw material tank and the processing container. In the gas supply line, a flow meter, a tank configured to temporarily store a gas, and a valve are installed in this order toward a downstream side.

### PRIOR ART DOCUMENTS

### Patent Documents

Patent Document 1: Japanese Laid-Open Patent Publication No. 2018-145458

The present disclosure provides a technique capable of improving accuracy of detecting a flow rate of a raw material gas which is included in a processing gas supplied to a substrate.

### SUMMARY

A gas supply device of the present disclosure, which is a gas supply device that supplies a processing gas to a processing container storing a substrate and performs a process, includes:

a raw material container configured to accommodate a liquid raw material or a solid raw material;

a carrier gas supply configured to supply a carrier gas into the raw material container;

a gas supply path configured to supply the processing gas, which includes the raw material that has been vaporized and the carrier gas, from the raw material container to the processing container;

a flow meter provided in the gas supply path and configured to measure a flow rate of the processing gas; and

a constricted flow path provided on a downstream side of the flow meter in the gas supply path and configured to increase an average pressure value between the constricted flow path and the flow meter in the gas supply path.

According to the present disclosure, it is possible to improve accuracy of detecting a flow rate of a raw material gas which is included in a processing gas supplied to a substrate.

### BRIEF DESCRIPTION OF DRAWINGS

FIG. 1 is a vertical cross-sectional side view of a film forming apparatus including a gas supply device according to an embodiment of the present disclosure.

FIG. 2 is a schematic view illustrating a processing gas supply pipe provided in the film forming apparatus.

FIG. 3 is an explanatory view illustrating a pressure distribution in the processing gas supply pipe.

FIG. 4 is a graph for describing a detected flow rate.

FIG. 5 is a perspective view of an orifice provided in the processing gas supply pipe.

FIG. 6 is a flow chart illustrating a process of adjusting a flow rate of a raw material gas included in a processing gas.

FIG. 7 is an explanatory view illustrating a state in which a gas flows through the processing gas supply pipe.

FIG. 8 is an explanatory view illustrating a state in which a gas flows through the processing gas supply pipe.

FIG. 9 is a graph showing a result of an evaluation experiment.

FIG. 10 is a graph showing a result of an evaluation experiment.

FIG. 11 is a graph showing a result of an evaluation experiment.

FIG. 12 is a graph showing a result of an evaluation experiment.

### DETAILED DESCRIPTION

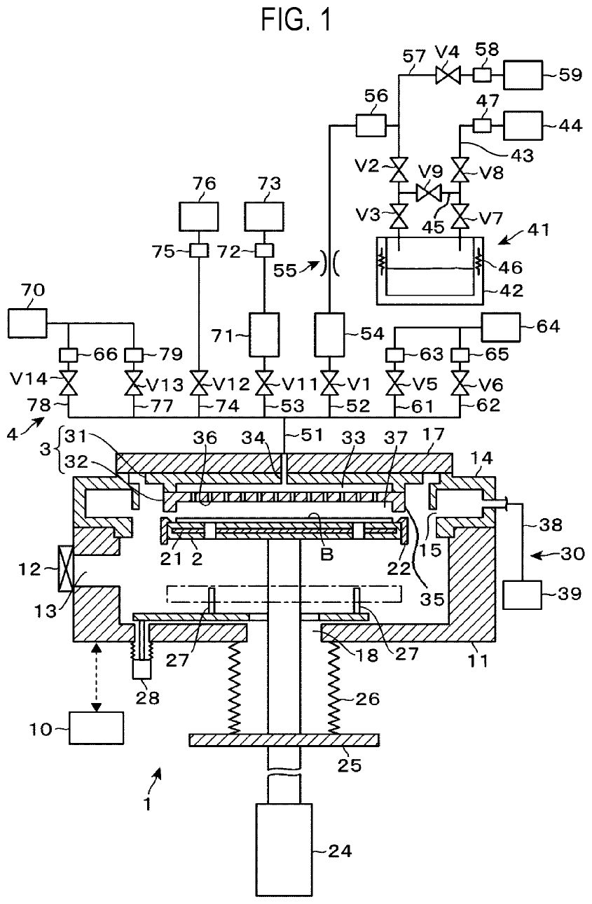

A film forming apparatus 1 including an embodiment of a gas supply device of the present disclosure will be described with reference to the vertical cross-sectional side view of FIG. 1. The film forming apparatus 1 includes a processing container 11, a stage 2 configured to horizontally support a wafer B in the processing container 11, a shower head 3 configured to supply a gas into the processing container 11 in a shower form, an exhauster 30 configured to evacuate an interior of the processing container 11, and a gas supply mechanism 4 configured to supply various gases to the shower head 3. The film forming apparatus 1 forms a W film on the wafer B through an ALD method in which a processing gas including tungsten pentachloride (WCl₅) gas as a raw material gas and H₂ gas as a reducing gas are alternately and repeatedly supplied into the processing container 11. Therefore, the above-mentioned processing gas is a film forming gas for forming a film on the wafer B. Between a period for supplying the processing gas and a period for supplying the reducing gas, N₂ gas is supplied as a purge gas for purging the interior of the processing container 11. Therefore, the film forming apparatus 1 is configured to repeat a cycle of supplying the processing gas, the purge gas, the reducing gas, and the purge gas in this order.

The processing container 11 has a circular shape, and a loading/unloading port 13 for the wafer B, which is opened and closed by a gate valve 12, is formed at a lower portion of a side wall of the processing container 11. An upper portion of the side wall of the processing container 11 is configured by an annular exhaust duct 14 having a rectangular vertical cross section. In addition, on an inner peripheral surface of the exhaust duct 14, a slit-shaped exhaust port 15 is opened along a circumference of the exhaust duct 14 to be in communication with a flow path 16 in the exhaust duct 14. On the exhaust duct 14, a peripheral edge portion of a ceiling plate 17 constituting a ceiling of the processing container 11 is provided.

The stage 2 has the wafer B placed on a central portion of a top surface thereof. In the stage 2, a heater 21 for heating the wafer B is embedded to heat the wafer B to a desired temperature during a film forming process. Reference numeral 22 in the drawings denotes a cover, which covers the stage 2 from the outside of a placement region of the wafer B on the top surface of the stage 2 to a side surface of the stage 2. The stage 2 is supported by a support column 23. A lower portion of the support column 23 extends outside the processing container 11 through a hole 18 provided in a bottom portion of the processing container 11, and is connected to a lifting mechanism 24. The lifting mechanism 24 moves the stage 2 vertically between a raised position indicated by the solid line in FIG. 1 and a lowered position indicated by the alternate long and short dash line below the raised position. The raised position is a position at the time of processing the wafer B, and the lowered position is a position at the time of delivering the wafer B to and from a transfer mechanism (not illustrated).

A flange 25 is provided on the support column 23 outside the processing container 11, and a bellows 26 is connected to the flange 25 and an outer peripheral edge portion of the hole 18, so that airtightness inside the processing container 11 is maintained. Three vertical pins 27 (only two are illustrated) are provided in a vicinity of a bottom surface of the processing container 11. The pins 27 move vertically by a lifting mechanism 28 to protrude or retract with respect to the top surface of the stage 2 at the lowered position. As a result, the wafer B is delivered between the transfer mechanism and the stage 2.

The shower head 3 is provided to face the stage 2, and includes a main body 31 fixed to a lower portion of the ceiling plate 17 of the processing container 11 and a shower plate 32 connected to the main body 31 from below. A gas diffusion space 33 surrounded by the main body 31 and the shower plate 32 is formed, and a downstream end of a gas introduction hole 34 that penetrates the main body 31 and the ceiling plate 17 of the processing container 11 is connected to the gas diffusion space 33. An annular protrusion 35 protruding downward is formed on a peripheral edge portion of the shower plate 32. A plurality of gas ejection holes 36 in communication with the gas diffusion space 33 is dispersedly opened in a region inward of the annular protrusion 35 on a bottom surface of the shower plate 32. When the stage 2 is located at the raised position, the annular protrusion 35 and the cover 22 of the stage 2 come close to each other, so that a space interposed between the bottom surface of the shower plate 32 inward of the annular protrusion 35 and the top surface of the stage 2 form a processing space 37.

The exhauster 30 includes an exhaust pipe 38 connected to the exhaust duct 14, and an exhaust mechanism 39 which is connected to a downstream side of the exhaust pipe 38 and includes a vacuum pump, a pressure control valve, and the like. The interior of the processing container 11 is evacuated through the exhaust duct 14 by the exhaust mechanism 39, and a vacuum atmosphere having a desired pressure is formed therein.

Subsequently, the gas supply mechanism 4 which is a gas supply device will be described. The gas supply mechanism 4 includes a WCl₅ gas supply 41, various gas sources, and a piping system configured to supply gases from the respective gas sources and the WCl₅ gas supply 41 to the shower head 3. In addition, as will be described later, the gas supply mechanism 4 also includes valves, a flow meter (a mass flow meter (MFM)), mass flow controllers (MFCs), buffer tanks, and an orifice that are interposed in gas supply pipes constituting the piping system.

A downstream end of a gas supply pipe 51 is connected to the gas introduction hole 34 of the ceiling plate 17 of the processing container 11. An upstream side of the gas supply pipe 51 branches to form a processing gas supply pipe 52 and a reducing gas supply pipe 53. An upstream end of the processing gas supply pipe 52 is connected to a raw material container 42 that constitutes the processing gas supply 41 via a valve V1, a buffer tank 54, a ring plate 50 (not illustrated in FIG. 1) forming an orifice 55, an MFM 56, and valves V2 and V3 in this order. An interior of the processing gas supply pipe 52 forms a processing gas supply path, and the orifice 55 forms a constricted flow path in the processing gas supply path. Then, by opening and closing the valve V1, a supply and cut-off of the processing gas is performed with respect to the interior of the processing container 11. Respective components such as the ring plate 50 other than the valve V1 interposed in the processing gas supply pipe 52 will be described in detail later.

The processing gas supply pipe 52 branches at a portion between the MFM 56 and the valve V2 to form a gas supply pipe 57. An upstream end of the gas supply pipe 57 is connected to a N₂ gas source 59 via a valve V4 and an MFC 58 in this order. N₂ gas supplied from the gas source 59 to the gas supply pipe 57 is a dilution gas that dilutes WCl₅ gas in the processing gas flowing through the processing gas supply pipe 52.

The processing gas supply pipe 52 branches at a downstream side of the valve V1, and an upstream side of the branching pipe further branches into two to form gas supply pipes 61 and 62. An upstream end of the gas supply pipe 61 is connected to a N₂ gas source 64 via a valve V5 and an MFC 63 in this order. An upstream end of the gas supply pipe 62 is connected to the gas supply pipe 61 at an upstream side of an MFC 65 via the valve V5 and the MFC 65 in this order. The gas supply pipe 61 is a line that supplies N₂ gas to the wafer B in order to purge the interior of the processing container 11. The gas supply pipe 62 is a line that constantly supplies N₂ gas into the processing container 11 during the film forming process.

An upstream end of the reducing gas supply pipe 53 is connected to a H₂ gas source 73 via a valve V11, a buffer tank 71, and an MFC 72 in this order. The buffer tank 71 has a role of supplying a large amount of gas into the processing container 11 in a short time, similarly to the buffer tank 54 to be described in detail later. In addition, the reducing gas supply pipe 53 branches at a downstream side of the valve V11 to form a gas supply pipe 74. An upstream end of the gas supply pipe 74 is connected to a H₂ gas source 76 via a valve V12 and an MFC 75 in this order. H₂ gas supplied from the H₂ gas source 76 is an additive gas that is supplied into the processing container 11 when WCl₅ gas is supplied to the wafer B and activates the WCl₅ supplied to the wafer B.

The gas supply pipe 74 branches at a downstream of the valve V12, and an upstream side of the branching pipe further branches into two to form gas supply pipes 77 and 78. An upstream end of the gas supply pipe 77 is connected to a N₂ gas source 70 via a valve V13 and an MFC 79 in this order. An upstream end of the gas supply pipe 78 is connected to the gas supply pipe 77 at an upstream side of an MFC 79 via a valve V14 and the MFC 66 in this order. The gas supply pipe 77 is a line that supplies N₂ gas to the wafer B in order to purge the interior of the processing container 11. The gas supply pipe 78 is a line that constantly supplies N₂ gas into the processing container 11 during the film forming process.

Subsequently, the processing gas supply 41 will be described. The processing gas supply 41 includes a raw material container 42, a carrier gas supply pipe 43, a N₂ gas source 44 for supplying N₂ gas as a carrier gas to the raw material container 42, and a bypass pipe 45. The raw material container 42 accommodates WCl₅ which is a solid-state film-forming raw material and includes a heater 46 for heating and sublimating the WCl₅ to produce WCl₅ gas. An upstream end of the processing gas supply pipe 52 and a downstream end of the carrier gas supply pipe 43 are open in a gas phase region in the raw material container 42. An upstream end of the carrier gas supply pipe 43 is connected to the N₂ gas source 44 via valves V7 and V8 and an MFC 47. The carrier gas supply pipe 43, the valves V7 and V8, the MFC 47, and the N₂ gas source 44 constitute a carrier gas supply. In addition, a portion of the processing gas supply pipe 52 between the valves V2 and V3 and a portion of the carrier gas supply pipe 43 between the valves V7 and V8 are connected to each other by the bypass pipe 45 having a valve V9 interposed therein.

By configuring the processing gas supply 41 as described above, the carrier gas can be supplied into the raw material container 42, and the processing gas including the WCl₅ gas and the carrier gas can be supplied to the processing gas supply pipe 52. A flow rate of the WCl₅ gas in the processing gas supplied to the processing gas supply pipe 52 as described above increases as a flow rate of the carrier gas supplied to the raw material container 42 increases. During the film forming process, for example, the carrier gas is supplied to the raw material container 42 at a constant flow rate, and the processing gas is constantly supplied to the processing gas supply pipe 52.

When supplying the processing gas to the processing gas supply pipe 52 as described above, only the valve V9 of the bypass pipe 45 is closed among the valves V2, V3, and V7 to V9 constituting the processing gas supply 41. In addition, by closing the valves V3 and V7 and opening the valves V2, V8, and V9, the carrier gas can be supplied to the processing gas supply pipe 52 via the bypass pipe 45 without passing through the raw material container 42. That is, of the WCl₅ gas and the carrier gas, the carrier gas can be independently supplied to the processing gas supply pipe 52. In other words, the carrier gas can be supplied to the processing gas supply pipe 52 by bypassing the raw material container 42.

The buffer tank 54 provided in the processing gas supply pipe 52 is provided to supply a relatively large flow rate of the processing gas to the processing container 11 in a short time. More specifically, in order to perform the ALD method, the valve V1 of the processing gas supply pipe 52 is repeatedly opened and closed during the film forming process, that is, while the processing gas is being supplied to the processing gas supply pipe 52 as described above. The processing gas supplied as described above from the processing gas supply 41 while the valve V1 is closed is supplied to and temporarily stored in the buffer tank 54. Then, when the valve V1 is opened, the processing gas is discharged from the buffer tank 54 into the processing container 11 at a relatively large flow rate, and the process is performed quickly. In order to perform one cycle of the ALD method at high speed, the opening and closing of the valve V1 is also performed at high speed.

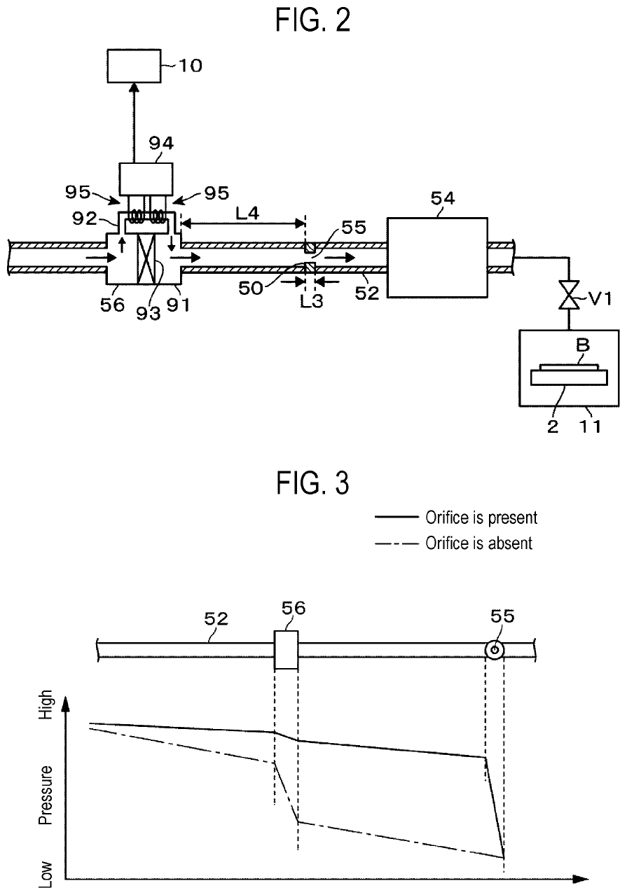

There are no restrictions on the configuration of the above-mentioned MFM 56 used, but FIG. 2 illustrates an example of the configuration for the sake of description. The MFM 56 illustrated in this drawing is, for example, a thermal flow meter, and includes a main flow path 91 for gas and a thin tube 92 for connecting an upstream side and a downstream side of the main flow path 91 to each other. In the drawing, reference numeral 93 denotes a resistance body with respect to a gas flow provided in the main flow path 91, and the thin tube 92 forms a flow path that bypasses the resistance body 93. Due to the action of the resistance body 93, in the MFM 56, a ratio of a flow rate of the gas flowing through the thin tube 92 toward an outlet of the MFM 56 and a flow rate of the gas flowing toward the outlet of the MFM 56 without flowing through the thin tube 92 becomes constant.

A coil 95, which is a heating element connected to a bridge circuit 94, is wound on each of the upstream side and the downstream side of the thin tube 92. The bridge circuit 94 transmits a detection signal to a controller 10 described later. The controller 10 calculates a flow rate of the gas flowing through the MFM 56 based on the detection signal. Unless otherwise specified, the flow rate in the present specification does not mean an integrated flow rate but a flow rate per unit time. For example, by providing the resistance body 93 as described above, a conductance in the MFM 56 is smaller than a conductance in the processing gas supply pipe 52.

In order to form the W film having a desired thickness on the wafer B, it is necessary to detect a flow rate of the WCl₅ gas in the processing gas with high accuracy at the time of film forming process or at the time of adjusting the flow rate of the WCl₅ gas before the film forming process. In order to obtain the flow rate of the WCl₅ gas, a difference between a first detection value by the MFM 56 when supplying the processing gas to the processing gas supply pipe 52 and a second detection value by the MFM 56 when the carrier gas is supplied to the processing gas supply pipe 52 by bypassing the raw material container 42 may be calculated. That is, the flow rate may be measured by the MFM 56 under the same condition, except for a distribution route of the carrier gas, and the difference between the respective measurement results may be calculated.

The orifice 55 of the processing gas supply pipe 52 is provided in order to improve accuracy of the flow rate of the WCl₅ gas when calculating the flow rate of the WCl₅ gas as described above. Hereinafter, in order to describe an operation of the orifice 55, FIG. 3 is also referred to as appropriate. In the graph of FIG. 3, a pressure distribution in a length direction of the processing gas supply pipe 52 when the valve V1 is opened to flow the gas therethrough is illustrated in correspondence to a schematic view of the processing gas supply pipe 52 on an upper portion of the graph. In the graph, a horizontal axis and a vertical axis indicate a position of the processing gas supply pipe 52 in the flow path and a pressure in the flow path, respectively. In addition, in FIG. 3, a pressure distribution when the orifice 55 is provided and a pressure distribution when the orifice 55 is not provided are shown by a solid line graph and a chain line graph, respectively.

First, a gas state and a pressure distribution in the processing gas supply pipe 52 when the orifice 55 is not provided will be described. As described above, the conductance of the flow path of the MFM 56 is smaller than that of the processing gas supply pipe 52. Such a small conductance forms a large differential pressure between an inlet and an outlet of the MFM 56. Since the differential pressure is formed as described above, a flow velocity of the gas in the MFM 56 is high. When the valve V1 is switched from the opened state to the closed state, the flow velocity of the gas, which has been high in the MFM 56, is greatly reduced. Therefore, an amount of fluctuation of the gas flow velocity in the MFM 56 due to the opening and closing of the valve V1 is large. Since the valve V1 is repeatedly opened and closed at high speed as described above, such fluctuation in the gas flow velocity occurs in a short cycle. Since the flow velocity corresponds to the flow rate, as in the flow velocity, rapid changes are repeated in a short cycle in the flow rate and thus the flow rate also becomes unstable.

Subsequently, the case in which the orifice 55 is provided will be described. The conductance of the orifice 55 is smaller than that of the flow path of the MFM 56. By providing the orifice 55 configured as described above on a downstream side of the MFM 56, as illustrated in FIG. 3, when the gas flows through the processing gas supply pipe 52, the pressure of the flow path drops toward the downstream side of the processing gas supply pipe 52, and a large differential pressure is formed between the inlet and the outlet of the orifice 55. That is, a large pressure loss occurs in the orifice 55, and a pressure loss on an upstream side of the orifice 55 is suppressed.

More specifically, when the orifice 55 is provided, a differential pressure is formed in the orifice 55 so that the pressure in the flow path on the upstream side of the orifice 55 becomes higher, compared with the case when the orifice 55 is not provided. That is, the pressure on a downstream side of the MFM 56 increases, so that the differential pressure between the inlet and the outlet of the MFM 56 is suppressed and the flow velocity in the MFM 56 is also suppressed. By suppressing the flow velocity, the flow rate flowing through the MFM 56 is also suppressed. Therefore, as the valve V1 is repeatedly opened and closed, sudden fluctuation in the flow rate is suppressed.

In addition, by providing the orifice 55 as described above, the pressure in the flow path between the MFM 56 and the orifice 55 increases, compared with the case where the orifice 55 is not provided. More specifically, the orifice 55 is configured such that an average pressure value in the flow path between the MFM 56 and the orifice 55 increases compared with the case where the orifice 55 is not provided. This average pressure value is an average value of pressures obtained by arbitrarily setting, for example, three or more measurement positions, in the flow path between the MFM 56 and the orifice 55, to be spaced apart from one another in the length direction of the flow path and measuring pressures at the respective set measurement positions when the gas flows through the flow path.

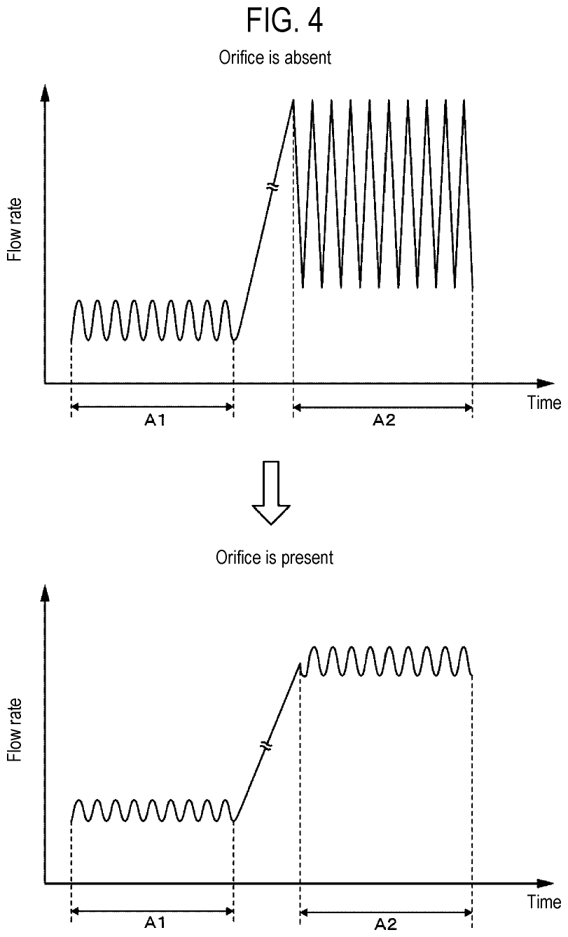

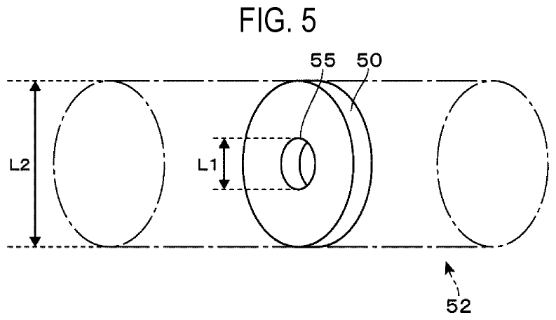

An upper portion and a lower portion of FIG. 4 are graphs schematically showing temporal changes in the flow rate detected by the MFM 56 when the orifice 55 is not provided and when the orifice 55 is provided, respectively. A horizontal axis of the graphs represents time, and a vertical axis of the graphs represents flow rate. The period A1 in the graphs is a period during which the carrier gas is supplied alone, and the period A2 is a period during which the processing gas is supplied. During the periods A1 and A2, the above-described valve V1 is repeatedly opened and closed. When the orifice 55 is not provided, a change in the flow rate is large, that is, a vibration of a waveform of the graph is large for the above-described reasons in both the periods A1 and A2. In particular, the vibration becomes large during the period A2 in which the flow rate of the gas flowing through the MFM 56 is large. As will also be shown in the evaluation experiments described later, due to such a large change in the flow rate, even when the flow rate of the WCl₅ gas is obtained by taking the difference between the flow rate value in the period A1 and the flow rate value in the period A2, there is a possibility that the flow rate may include a relatively large error. That is, there is a concern that a deviation may occur from an actual flow rate of the WCl₅ gas.

In contrast, when the orifice 55 is provided, the vibration of the waveform of the graph is small and the change in the flow rate is suppressed for the above-described reasons in both the periods A1 and A2. Therefore, when the flow rate of the WCl₅ gas is obtained by taking the difference between the flow rate value in the period A1 and the flow rate value in the period A2 as described above, the deviation of the obtained flow rate of the WCl₅ gas from the actual flow rate of the WCl₅ gas is suppressed.

Hereinafter, the configuration of the orifice 55 will be described in more detail with reference to the perspective view of FIG. 5 in addition to FIG. 2. The orifice 55 is a circular hole that opens in the circular ring plate 50. When a diameter of the orifice 55 is too large, a conductance of the orifice 55 becomes too large, and there is a concern that the effect of sufficiently suppressing the differential pressure of the MFM 56 cannot be obtained. When the diameter of the orifice 55 is too small, the conductance of the orifice 55 becomes too small, and there is a concern that the gas will not flow through the processing gas supply pipe 52. From this point of view, it is desirable to set a diameter L1 of the orifice 55 to be, for example, 0.5 mm to 2 mm, and when a flow path diameter (an internal diameter) of the processing gas supply pipe 52 is L2, it is desirable to set L1/L2 to be 1/10 to 1/2. In order to sufficiently suppress the conductance, a length L3 of the orifice 55 (see FIG. 2) is, for example, 1 mm.

In addition, a distance L4 along the flow path from the MFM 56 to the orifice 55 is, for example, 10 mm to 1,000 mm. In addition, a volume of the flow path from the MFM 56 to the orifice 55 is, for example, 1 cc to 1,000 cc. The orifice 55 is not limited to being provided on an upstream side of the buffer tank 54, and may be provided on a downstream side of the buffer tank 54. However, when the orifice 55 is disposed on the downstream side of the buffer tank 54 as described above, the flow of the processing gas is hindered, and there is a concern that a large amount of the processing gas cannot be supplied to the processing container 11 in a short time. Thus, it is desirable to provide the orifice 55 on the upstream side of the buffer tank 54.

Subsequently, the controller 10 (see FIG. 1), which is a computer provided in the film forming apparatus 1, will be described. The controller 10 includes a program. A group of steps are incorporated in the program so that a series of operations in the film forming apparatus 1 described later can be performed. According to the program, the controller 10 outputs control signals to respective components of the film forming apparatus 1, so that the operation of the respective components is controlled. Specifically, each operation, such as opening and closing of the respective valves, flow rate adjustment of the gases by the respective MFCs, vertical movement of the pins 27 by the lifting mechanism 28, vertical movement of the stage 2 by the lifting mechanism 24, evacuation of the interior of the processing container 11 by the exhaust mechanism 39, and heating of the wafer B by the heater 21, is controlled. In addition, reception of the detection signal from the MFM 56 and calculation of the flow rate of the raw material gas based on the detection signal is performed by the program. The program is stored in a storage medium such as a compact disk, a hard disk, a memory card, or a DVD, and is installed in the controller 10.

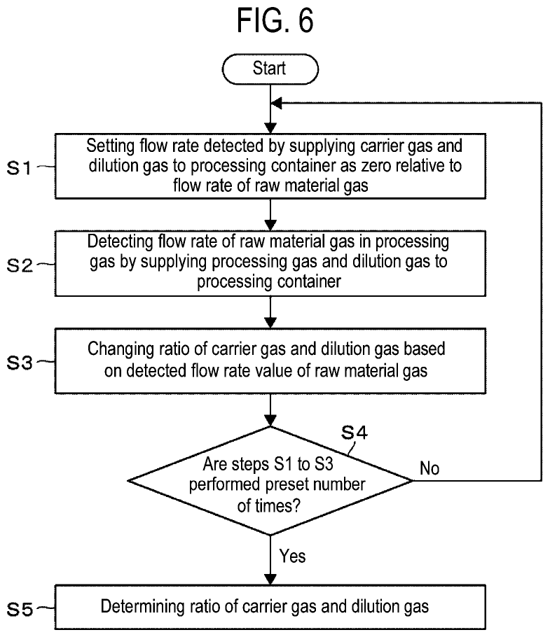

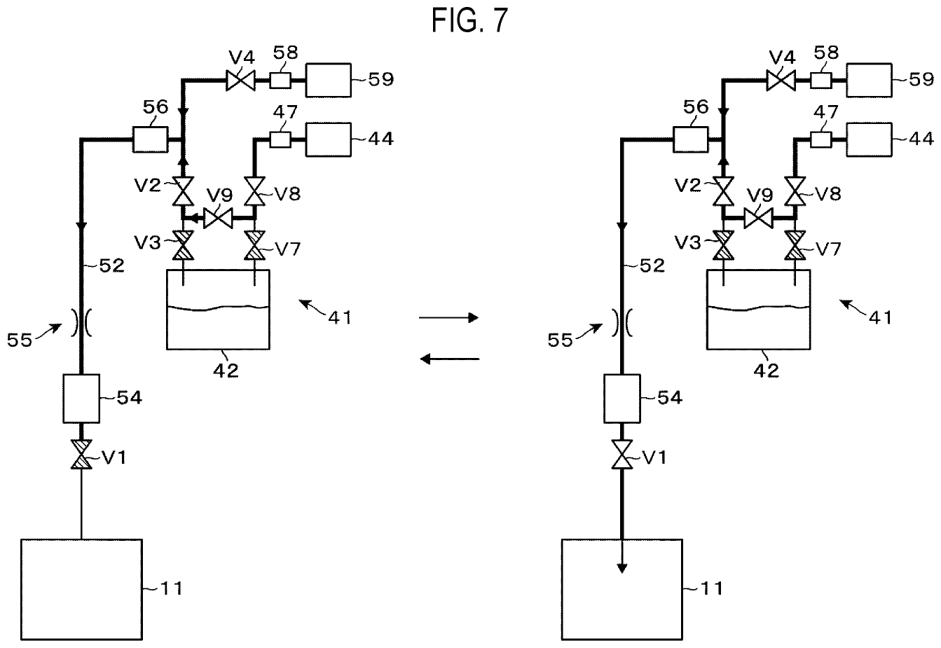

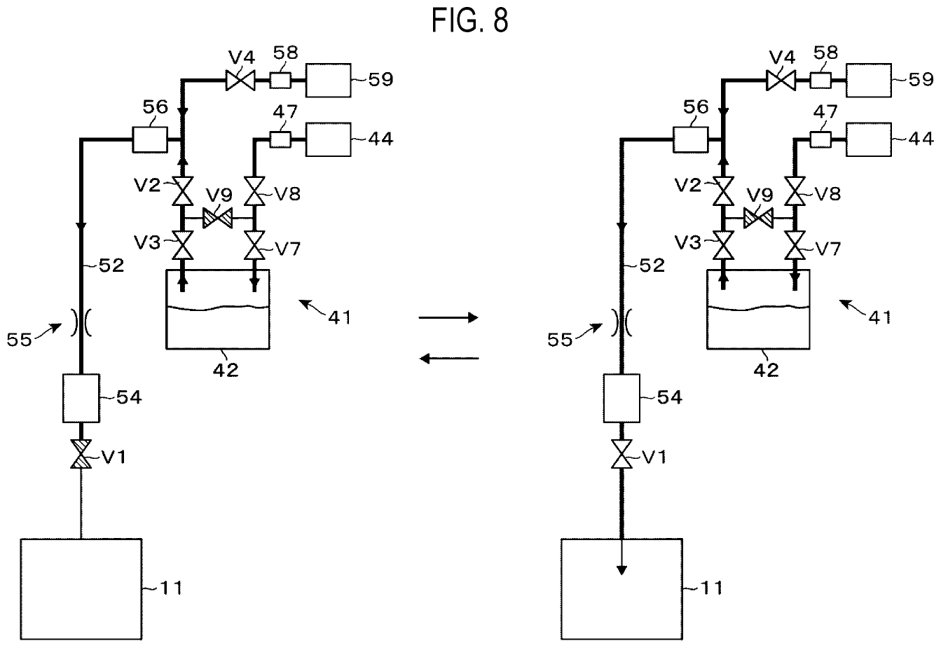

A process of adjusting a flow rate of the raw material gas (WCl₅ gas) performed before performing the film forming process in the film forming apparatus 1 will be described with reference to the flowchart of FIG. 6. This flow rate adjustment process is a process for setting the flow rate of the raw material gas in the processing gas supplied to the wafer B to a desired value at the time of the film forming process. More specifically, a ratio of a flow rate of the carrier gas supplied from the gas source 44 via the MFC 47 and a flow rate of the dilution gas supplied from the gas source 59 via the MFC 58 at the time of the film forming process is determined. FIGS. 7 and 8 are also referred to as appropriate for description. FIGS. 7 and 8 illustrate opened and closed states of the valves and flowing states of the gases in the processing gas supply pipe 52 and the respective pipes of the processing gas supply 41, in which the closed valves are hatched. As for the pipes, portions through which gases are flowing are shown thicker than portions through which gases are not flowing.

The wafer B is not accommodated in the processing container 11, and the interior of the processing container 11 has a vacuum atmosphere with a preset pressure. Then, from a state in which each valve is closed, the valves V2, V4, V8, and V9 are opened, and the opening and closing of the valve V1 is repeated as in the case of performing the film forming process. A left-hand side portion and a right-hand side portion of FIG. 7 show a state in which the valve V1 is closed and a state in which the valve V1 is opened, respectively. By the operations of the respective components as described above, the dilution gas (N₂ gas) and the carrier gas (N₂ gas) that has passed through the bypass pipe 45 are supplied to the processing gas supply pipe 52, and further intermittently supplied into the processing container 11. The flow rate of the carrier gas supplied from the gas source 44 via the MFC 47 and the flow rate of the dilution gas supplied from the gas source 59 via the MFC 58 are set to be values, which are preset as flow rates thereof at the time of the film forming process, respectively.

The controller 10 acquires detection signals transmitted from the MFM 56 while the valve V1 is repeatedly opened and closed and the dilution gas and the carrier gas are supplied to the processing container 11 as described above. Thereafter, the valves V1, V2, V4, V8, and V9 are closed to stop the supply of the dilution gas and the carrier gas into the processing container 11. Then, an average flow rate value is calculated from the detection signals obtained during a specific period. Assuming that opening and closing of the valve V1 once is a single opening/closing cycle, for example, this specific period is a time period during which ten opening/closing cycles including the last opening/closing cycle are performed. The average flow rate value calculated as described above is set as a flow rate when the flow rate of the WCl₅ gas, which is the raw material gas, is zero. That is, a process corresponding to zero point adjustment of the MFM 56 is performed (step S1).

Subsequently, from the state in which each valve is closed, the valves V2 to V4, V7, and V8 are opened, the processing gas and the dilution gas are supplied into the processing container 11 via the processing gas supply pipe 52, and the valve V1 is repeatedly opened and closed in the same manner as in step S1. A left-hand side portion and a right-hand side portion of FIG. 8 illustrate a state in which the valve V1 is closed and a state in which the valve V1 is opened, respectively. By the operations of the respective components as described above, the processing gas including the dilution gas is supplied to the processing gas supply pipe 52, and further intermittently supplied into the processing container 11. The flow rate of the carrier gas supplied from the gas source 44 via the MFC 47 and the flow rate of the dilution gas supplied from the gas source 59 via the MFC 58 are the same as those in step S1 performed immediately before.

The controller 10 acquires detection signals transmitted from the MFM 56 while the valve V1 is being repeatedly opened and closed and the processing gas and the dilution gas are being supplied as described above. Thereafter, the valves V1 to V4, V7, and V8 are closed to stop the supply of the processing gas and the carrier gas into the processing container 11. Then, for example, the average flow rate value is calculated from the detection signals obtained during the aforementioned specific period, and this calculated value is used as the flow rate of the WCl₅ gas (step S2). That is, in steps S1 and S2, the difference between the average flow rate value acquired during the period A2 shown in the lower graph of FIG. 4 and the average flow rate value acquired during the period A1 can be calculated. As described above with reference to FIGS. 3 and 4, by the action of the orifice 55, the fluctuation of the flow rate value detected by the MFM 56 in steps S1 and S2 is suppressed, and the calculated flow rate value of the WCl₅ gas becomes highly accurate.

The controller 10 calculates a difference between the calculated flow rate of the WCl₅ gas and a target value, and based on the difference, changes the setting of the ratio of the flow rate of the dilution gas to the flow rate of the carrier gas at the time of the film forming process so that the flow rate of the WCl₅ gas becomes the target value (step S3). That is, the settings of the MFCs 47 and 58 are changed. The above-described change of the ratio of the carrier gas and the dilution gas is performed such that a total flow rate of the flow rate of the carrier gas and the flow rate of the dilution gas is not changed.

Next, it is determined whether or not steps S1 to S3 have been performed a preset number of times (step S4). When it is determined that steps S1 to S3 have been performed the preset number of times, the flow rate of the carrier gas and the flow rate of the dilution gas, which have been set in last-performed step S3, are determined as the flow rate of the carrier gas and the flow rate of the dilution gas at the time of the film forming process, respectively (step S5). When it is determined in step S4 that steps S1 to S3 have not been performed the preset number of times, each step after step S1 is performed again.

Next, the film forming process for the wafer B performed after the process of adjusting the flow rate of the raw material gas will be described with reference to FIG. 1. It is assumed that the processing gas in the following description of the film forming process includes a dilution gas. The wafer B is loaded into the processing container 11, and the interior of the processing container 11 is turned into a vacuum atmosphere having a desired pressure. Subsequently, from a state in which each valve is closed, the valves V6 and V14 are opened, and N₂ gas is supplied into the processing container 11 via the gas supply pipes 62 and 78. Subsequently, the valves V2, V3, V7, and V8 are opened, and the carrier gas and the dilution gas are supplied from the gas sources 44 and 59 via the MFCs 47 and 58, respectively, at the flow rates determined in step S5 of the flow rate adjustment process. Thus, the processing gas is stored in the buffer tank 54 as illustrated on the left-hand side portion of FIG. 8. In addition, H₂ gas is supplied to and stored in the buffer tank 71.

Next, the valve V1 is opened, and the processing gas stored in the buffer tank 71 is supplied into the processing container 11 as illustrated on the right-hand side portion of FIG. 8. In addition, when the valve V1 is opened, the valve V12 is opened, so that H₂ gas as an additive gas is supplied to the processing container 11 via the gas supply pipe 74 (step T1). WCl₅ is adsorbed on the wafer B, and the WCl₅ is activated by the action of the H₂ gas. Subsequently, the valve V1 is closed, and the supply of the processing gas into the processing container 11 is stopped. Then, the valves V5 and V13 are opened, and the purge gas is supplied into the processing container 11 via the gas supply pipes 61 and 77. Thus, the interior of the processing container 11 is purged (step T2). By closing the valve V1, the processing gas is stored in the buffer tank 54 again.

Thereafter, the valves V5 and V13 are closed, and the supply of the purge gas into the processing container 11 is stopped. Then, the valve V11 is opened, and H₂ gas as a reducing gas is supplied into the processing container 11 via the reducing gas supply pipe 53. Thus, the WCl₅ adsorbed on the wafer B is reduced to form a thin layer of W (step T3). Subsequently, the valve V11 is closed and the supply of H₂ gas into the processing container 11 is stopped. Then, the valves V5 and V13 are opened, and the purge gas is supplied into the processing container 11 via the gas supply pipes 61 and 77. Thus, the interior of the processing container 11 is purged (step T4). The cycle including steps T1 to T4 described above is repeated, and the thin layer of W is deposited on the wafer B to form a W film. When the W film becomes a desired thickness, the cycles of steps T1 to T4 are stopped, and the wafer B is unloaded from the processing container 11.

While performing the respective steps (i.e., steps T1 to T4) of the film forming process, the controller 10 receives detection signals output from the MFM 56 and acquires the flow rate of the WCl₅ gas. Then, the average flow rate value of the WCl₅ gas is calculated. When there is a deviation between this average value and the target value, the setting of the ratio of the flow rate of the carrier gas and the flow rate of the dilution gas is changed by the amount corresponding to the deviation. That is, after the same setting adjustment as in step S3 in the process of adjusting the flow rate of the raw material gas described above is performed, a subsequent wafer B is processed.

With this film forming apparatus 1, the flow rate of the WCl₅ gas included in the processing gas can be detected with high accuracy. Therefore, in forming a W film on each wafer B, a thickness of the W film can be adjusted to a target value with high accuracy. In forming the W film, the solid raw material accommodated in the raw material container 42 is not limited to WCl₅, but may be tungsten hexachloride (WCl₆). In addition, when the film formation is performed using a solid raw material, the film formation is not limited to formation of the W film. For example, a ruthenium film may be formed using ruthenium carbonyl (Ru₃(CO)₁₂) as a solid raw material. In addition, this technique is also applicable to, for example, a case in which a tantalum film is formed using a gas obtained by vaporizing solid tantalum chloride at room temperature and a reducing gas.

In addition, this technique is applicable not only to a case in which a solid raw material is vaporized and a wafer B is processed as described above, but also to a case in which a liquid raw material is vaporized and a wafer B is processed. For example, tantalum oxide may be formed into a film using a gas obtained by vaporizing pentaethoxy tantalum, which is a liquid raw material, and an oxidizing gas. In addition, the present technique is not limited to being applied to a film forming apparatus that performs an ALD method, but may be applied to a film forming apparatus that performs a chemical vapor deposition (CVD) method. Furthermore, the present technique is not limited to being applied to a film forming process only. For example, the present technique is also applicable to a case in which a carrier gas is supplied to a container that accommodates a fluorocarbon-based liquid, the liquid is vaporized to generate an etching gas, and the etching gas is used to etch a silicon oxide-based film on a surface of a wafer B. That is, the raw material accommodated in the raw material container 42 may be any raw material that produces a gas for processing a substrate, and is not limited to a film forming raw material. More specifically, the present technique is applicable to a supply system in which it is necessary to supply a raw material gas, which is generated from a solid or liquid raw material having a vapor pressure lower than a processing pressure for performing a process within the processing container 11, into the processing container 11 by using a carrier gas.

In addition, in the above-described example, the orifice 55 forms a portion of the flow path of the processing gas supply pipe 52 to form a constricted flow path, but the present disclosure is not limited to providing the orifice 55. The processing gas supply pipe 52 may be configured such that, for example, a portion thereof on the downstream side of the MFM 56 has a diameter reduced toward a downstream side. That is, the conductance may be reduced by configuring a portion of the processing gas supply pipe 52 as a wrapper tube to form a constricted flow path. In addition, in the above-described example, the buffer tank 54 is provided as a gas storage, but the gas storage may not be provided. Instead of providing the buffer tank 54 as the gas storage, a portion of the processing gas supply pipe may be expanded in diameter so that the effect of temporarily storing a large amount of gas can be obtained as in the buffer tank 54.

Although an example of an MFM is illustrated for easy understanding, the MFM is not limited to the above-described configuration. For example, the MFM may be configured by bending the main flow path 91. In addition, the MFM is not limited to the thermal flow meter, but may be, for example, a differential pressure flow meter that detects pressures before and after the resistance body 93 and detects a flow rate based on a differential pressure thereof. In the above-described example, a difference between an average flow rate value in an arbitrary period in the period A1 for bypassing the carrier gas and an average flow rate value in an arbitrary period in the period A2 for supplying the processing gas is calculated, and the calculated value is set to be the flow rate of the WCl₅ gas. Without being limited to the calculation described above, for example, a difference may be calculated at start timings of the periods A1 and A2 to obtain a change of the flow rate of the WCl₅ gas during the process.

The embodiments disclosed herein should be considered to be exemplary in all respects and not restrictive. The above-described embodiments may be omitted, replaced, modified, or combined in various forms without departing from the scope and spirit of the appended claims.

### EVALUATION EXPERIMENTS

Next, evaluation experiments conducted in connection with the present technique will be described.

### Evaluation Experiment 1

As Evaluation Experiment 1, using the film forming apparatus 1 described with reference to FIG. 1, the valve V1 was repeatedly opened and closed and the processing gas was supplied to the processing container 11 as in the film forming process described above. During that period, detection signals output from the MFM 56 were acquired, and the detected flow rate was monitored. That is, the flow rate was detected in the state in which the orifice 55 was provided in the processing gas supply pipe 52. In addition, as Comparative Experiment 1, a flow rate was detected under the same conditions as in Evaluation Experiment 1, except that the orifice 55 was not provided in the processing gas supply pipe 52.

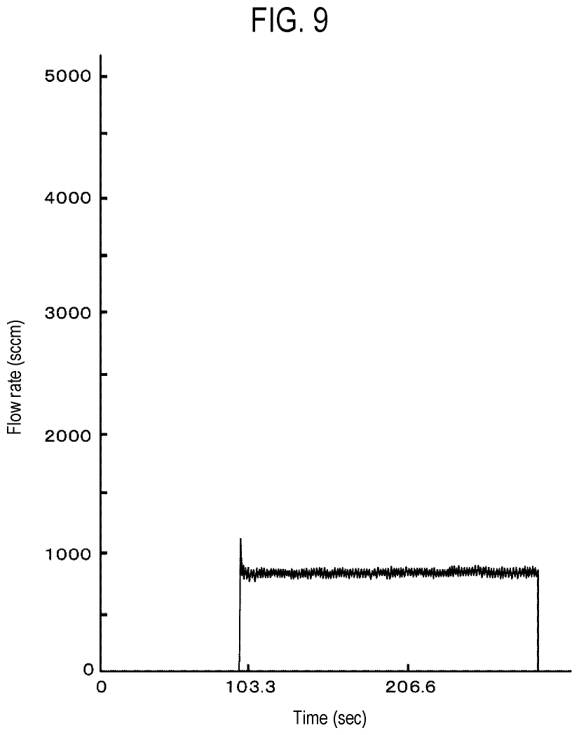

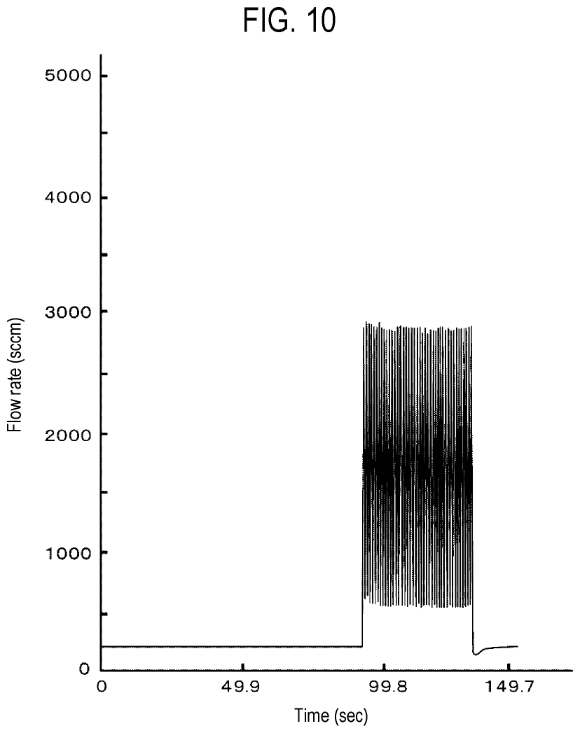

FIGS. 9 and 10 are graphs showing the results of Evaluation Experiment 1 and Comparative Experiment 1, respectively. The horizontal axis of each graph represents an elapsed time (unit: seconds), and the vertical axis of each graph represents a detected flow rate (unit: sccm). As illustrated in FIG. 10, in Comparative Experiment 1, as described with reference to FIG. 4, the vibration of the waveform of the graph, that is, a fluctuation range of the flow rate, is large. However, as illustrated in FIG. 9, in Evaluation Experiment 1, it can be recognized that the fluctuation range is suppressed. Therefore, Evaluation Experiment 1 showed, as described with reference to FIG. 4, the effect that the fluctuation of the detected flow rate can be suppressed by providing the orifice 55.

### Evaluation Experiment 2

As Evaluation Experiment 2, the valve V1 was repeatedly opened and closed and the processing gas was supplied to the processing container 11 in the state where the orifice 55 was provided in the processing gas supply pipe 52 as in Evaluation Experiment 1. The processing gas was supplied five times under the same condition as one another, and a change of the calculated flow rate value of the raw material gas was investigated each time. In addition, as Comparative Experiment 2, the same experiment as Evaluation Experiment 2 was performed, except that the orifice 55 was not provided in the processing gas supply pipe 52.

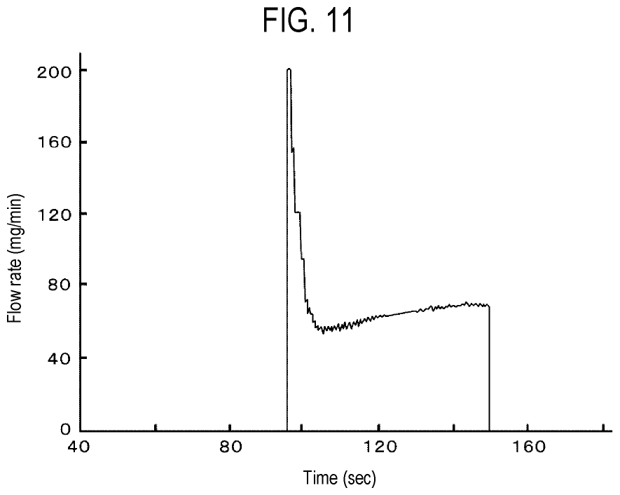

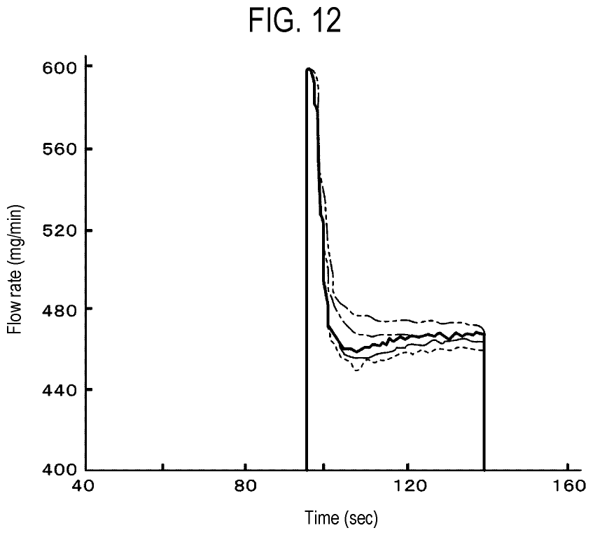

FIGS. 11 and 12 are graphs showing results of Evaluation Experiment 2 and Comparative Experiment 2, respectively. Similar to the graphs of FIGS. 9 and 10, a horizontal axis and a vertical axis of each graph of FIGS. 11 and 12 represent an elapsed time and a flow rate, respectively. However, the graphs of FIGS. 11 and 12 show the flow rates of WCl₅ gas calculated by receiving detection signals output from the MFM 56 after performing a process corresponding to the zero point adjustment of the MFM 56 (step S1) by the controller 10. The unit of flow rate is mg/min. In the graph of FIG. 12, results of respective measurement times are shown by different types of lines. As shown in this graph, in Comparative Experiment 2, it was confirmed that, for each measurement time, a deviation occurred in the change of the flow rate of the raw material gas calculated. In Evaluation Experiment 2, since the changes of the flow rates in the respective measurement times were substantially the same and lines of the graph overlapped with one another, only one line type is shown in FIG. 11. Therefore, from Evaluation Experiment 2, it was confirmed that reproducibility in repeating the detection of the flow rate of the raw material gas is improved by providing the orifice 55. It is considered that such improvement of the reproducibility indicates improvement of the detection accuracy.

### EXPLANATION OF REFERENCE NUMERALS

B: wafer, 10: controller, 11: processing container, 4: gas supply mechanism, 42: raw material container, 52: processing gas supply pipe, 55: orifice, 56: MFM

1-6. (canceled)

7. A gas supply device that supplies a processing gas to a processing container storing a substrate and performs a process, the gas supply device comprising:
a raw material container configured to accommodate a liquid raw material or a solid raw material;
a carrier gas supply configured to supply a carrier gas into the raw material container;
a gas supply path configured to supply the processing gas, which includes the raw material that has been vaporized and the carrier gas, from the raw material container to the processing container;
a flow meter provided in the gas supply path and configured to measure a flow rate of the processing gas; and
a constricted flow path provided on a downstream side of the flow meter in the gas supply path and configured to increase an average pressure value between the constricted flow path and the flow meter in the gas supply path.

8. The gas supply device of claim 7, further comprising a valve provided on a downstream side of the constricted flow path in the gas supply path and configured to perform supply and cut-off of the processing gas with respect to the processing container.

9. The gas supply device of claim 8, further comprising a gas storage provided on the downstream side of the flow meter in the gas supply path and configured to temporarily store the processing gas,
wherein the constricted flow path is provided between the valve and the gas storage.

10. The gas supply device of claim 9, wherein the constricted flow path is an orifice.

11. The gas supply device of claim 10, wherein the processing gas is a film forming gas for performing film formation on the substrate.

12. The gas supply device of claim 7, wherein the constricted flow path is an orifice.

13. The gas supply device of claim 7, wherein the processing gas is a film forming gas for performing film formation on the substrate.

14. A gas supply method that supplies a processing gas to a processing container storing a substrate and performs a process, the gas supply method comprising:
supplying a carrier gas to a raw material container accommodating a liquid raw material or a solid raw material;
supplying the processing gas, which includes the raw material that has been vaporized and the carrier gas, from the raw material container to the processing container by causing the raw material to flow through a gas supply path; and
measuring a flow rate of the processing gas by a flow meter provided in the gas supply path,
wherein a constricted flow path configured to increase an average pressure value between the constricted flow path and the flow meter in the gas supply path is provided on a downstream side of the flow meter in the gas supply path.
